(19) United States
(12) Patent Application Publication
(10) Pub. No.: US 2025/0308918 A1
(43) Pub. Date: Oct. 2, 2025

(54) SELECTIVE OXIDE ETCH USING LIQUID PRECURSOR

(71) Applicant: Lam Research Corporation, Fremont, CA (US)

(72) Inventors: Adrien Camille GUILLAUSSIER, San Francisco, CA (US); Mark Naoshi KAWAGUCHI, San Carlos, CA (US); Ji ZHU, Castro Valley, CA (US); Seung-Ho PARK, San Jose, CA (US)

(21) Appl. No.: 18/855,086

(22) PCT Filed: Mar. 16, 2023
(86) PCT No.: PCT/US2023/064577

§ 371 Date: Oct. 8, 2024

Related U.S. Application Data
(60) Provisional application No. 63/362,911, filed on Apr. 13, 2022.

(51) Int. Cl. H01L 21/311; H01L 21/67

(52) U.S. Cl. CPC H01L 21/31116; H01L 21/67069

(57) ABSTRACT

Embodiments herein relate to methods and apparatus for etching a substrate. In particular, the substrate is a semiconductor substrate and the material being etched is an oxide material such as silicon oxide. In various embodiments, the method may include receiving a substrate having an oxide material thereon; and exposing the substrate to a reactant gas to etch the oxide material on the substrate, where the reactant gas is in a vapor phase and comprises an ammonium-based hydroxide source.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Semiconductor fabrication often involves patterning schemes and other processes whereby some materials are selectively etched to prevent etching of other exposed surfaces of a substrate. As device geometries become smaller and smaller, high etch selectivity processes are desirable to achieve effective etching of desired materials without plasma assistance.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Various embodiments herein relate to methods and apparatus for etching a semiconductor substrate.

Various embodiments herein relate to methods, apparatus, and systems for etching a substrate. The substrate is typically a semiconductor substrate. In one aspect of the disclosed embodiments, a method of etching a substrate is provided, the method including: receiving a substrate having an oxide material thereon; and exposing the substrate to a reactant gas to etch the oxide material on the substrate, where the reactant gas is in a vapor phase and comprises an ammonium-based hydroxide source.

In various embodiments, the reactant gas is generated, at least in part, by vaporizing a solution comprising the ammonium-based hydroxide source and a solvent. In some embodiments, exposing the substrate to reactant gas includes: exposing the substrate to the reactant gas at a first temperature to form a salt on the substrate, and exposing the substrate to a second temperature to remove the salt from the substrate, where the second temperature is higher than the first temperature. In various embodiments, the first temperature is about 90° C. or less, and the second temperature is about 100° C. or greater. In some embodiments, the first temperature is about 50° C. or greater. In these or other embodiments, a difference between the first temperature and the second temperature may be about 60° C. or less. In some embodiments, the difference between the first temperature and the second temperature is about 20° C. or less.

In some embodiments, the substrate is exposed to the reactant gas and to the first temperature and the second temperature within a single reaction chamber.

In some embodiments, the oxide material is heterogeneous with respect to oxide density. For instance, in some embodiments the oxide material includes a first portion that is heterogeneous with respect to oxide density and a second portion that is homogeneous with respect to oxide density. In some such embodiments, exposing the substrate to the reactant gas includes exposing the first portion of the oxide material to the reactant gas, and exposing the second portion of the oxide material to a second reactant gas, where the second reactant gas includes a solvent and a halogen source, and does not include the ammonium-based hydroxide source. In various embodiments, the first portion of the oxide material is etched in a cyclic manner and the second portion of the oxide material is etched in a continuous, non-cyclic manner. In some embodiments, the second reactant gas includes pyridine. In these or other embodiments, the solvent may include isopropyl alcohol. In these or other embodiments, the halogen source may include HF.

Various chemistries may be used. In some embodiments, the ammonium-based hydroxide source includes ammonium hydroxide or a substituted form of ammonium hydroxide.

In some embodiments, the ammonium-based hydroxide source includes one or more alkyl groups bonded to a nitrogen of the ammonium-based hydroxide source. In some embodiments, the ammonium-based hydroxide source includes four alkyl groups bonded to the nitrogen of the ammonium-based hydroxide source. In some embodiments, the ammonium-based hydroxide source includes one or more reactant from the group consisting of tetramethylammonium hydroxide, tetraethylammonium hydroxide, tetrapropyl ammonium hydroxide, and combinations thereof.

The solution from which the reactant gas is at least partially generated may include one or more solvents. For example, in some embodiments the solution from which the reactant gas is at least partially generated includes water. In these or other embodiments, the solution from which the reactant gas is at least partially generated may include at least one solvent selected from the group consisting of acetone, acetonitrile, an alcohol, chloroform, dichlorobenzene, dichloroethane, dimethylacetamide, dimethylformamide, dimethylsulfoxide, formamide, hexamethylphosphoramide, nitrobenzene, nitromethane, pyridine, and combinations thereof.

In various embodiments, the reactant gas further includes a halogen source. In some embodiments, the halogen source is selected from the group consisting of HF, F₂, and combinations thereof.

In another aspect of the disclosed embodiments, an apparatus for etching a substrate is provided, the apparatus including: one or more process chambers, each process chamber including a substrate holder; one or more gas inlets into the process chambers and associated flow-control hardware; and a controller having at least one processor and a memory, where the at least one processor and the memory are communicatively connected with one another, the at least one processor is at least operatively connected with the flow-control hardware, and the memory stores computer-executable instructions for controlling the at least one processor to at least control the flow-control hardware to: cause the substrate to be exposed to a reactant gas, thereby causing removal of an oxide material from the substrate, where the reactant gas is in a vapor phase and comprises an ammonium-based hydroxide source.

These and other aspects are described further below with reference to the drawings.

### BRIEF DESCRIPTION OF THE DRAWINGS

FIG. 1 illustrates a method of etching silicon oxide from a substrate.

FIG. 2 describes a method of etching silicon oxide from a substrate according to various embodiments herein.

FIGS. 3 and 4 describe methods of etching silicon oxide from a substrate having both homogeneous and heterogeneous regions of silicon oxide according to various embodiments herein.

FIG. 5A depicts a cross-sectional side view of an example apparatus in accordance with disclosed embodiments.

FIG. 5B depicts a top view of a substrate heater with a plurality LEDs.

FIG. 5C depicts a top view of another substrate heater with a plurality LEDs.

FIG. 5D depicts the pedestal of FIG. 5A with additional features in accordance with various embodiments.

FIG. 5E depicts the pedestal of FIG. 5D with additional features in accordance with various embodiments.

FIG. 5F depicts a substrate support of FIGS. 5A and 5D in accordance with disclosed embodiments.

FIG. 6 provides experimental results showing the effectiveness of the disclosed methods.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

### Introduction and Context

Semiconductor fabrication processes often involve patterning and etching of various materials, including conductors, semiconductors, and dielectrics. Some examples include conductors, such as metals or carbon; semiconductors, such as silicon or germanium; and dielectrics, such as silicon oxide, aluminum dioxide, zirconium dioxide, hafnium dioxide, silicon nitride, and titanium nitride. Atomic layer etching (“ALE”) processes provide one class of etching techniques that involve repeated variations in etch conditions over the course of an etch operation. ALE processes remove thin layers of material using sequential self-limiting reactions. Generally, an ALE cycle is the minimum set of operations used to perform an etch process one time, such as etching a monolayer. The result of one ALE cycle is that at least some of a film layer on a substrate surface is etched. Typically, an ALE cycle includes a modification operation to form a reactive layer, followed by a removal operation to remove or etch only this reactive layer. The cycle may include certain ancillary operations such as removal of the reactants and/or byproducts. Generally, a cycle contains one instance of a unique sequence of operations.

As an example, a conventional ALE cycle may include the following operations: (i) delivery of a reactant gas to perform a modification operation, (ii) purging of the reactant gas from the chamber, (iii) exposure of the substrate to removal conditions (e.g., one or more of increased temperature, removal chemistry, and/or plasma) to perform a removal operation, and (iv) purging of the chamber. The modification operation generally forms a thin, reactive surface layer with a thickness less than the un-modified material. The reactant gas may be selected depending on the type and chemistry of the substrate to be etched.

In some instances, a purge may be performed after a modification operation. In a purge operation, non-surface-bound active etching reactant species may be removed from the process chamber. This can be done by purging and/or evacuating the process chamber to remove the active species, without removing the layer of modified material. Purging can be done using any inert gas such as N₂, Ar, Ne, He, and their combinations.

In a removal operation, the substrate may be exposed to an energy source to etch the substrate by directional sputtering (this may include activating or sputtering gas or chemically reactive species that induce removal). In some embodiments, the removal operation may be performed by ion bombardment using argon or helium ions. During removal, a bias may be optionally turned on to facilitate directional sputtering. In some embodiments, ALE may be isotropic; in some other embodiments ALE is not isotropic when ions are used in the removal process.

In various examples, the modification and removal operations may be repeated in cycles, such as about 1 to about 30 cycles, or about 1 to about 20 cycles. Any suitable number of ALE cycles may be included to etch a desired amount of film. In some embodiments, ALE is performed in cycles to etch about 1 Å to about 50 Å of the surface of the layers on the substrate. In some embodiments, cycles of ALE etch between about 2 Å and about 50 Å of the surface of the layers on the substrate. In some embodiments, each ALE cycle may etch at least about 0.1 Å, 0.5 Å, or 1 Å.

In some instances, prior to etching, the substrate may include a blanket layer of material, such as silicon or germanium. The substrate may include a patterned mask layer previously deposited and patterned on the substrate. For example, a mask layer may be deposited and patterned on a substrate including a blanket amorphous silicon layer. The layers on the substrate may also be patterned. Substrates may have “features” such as fins. or holes, which may be characterized by one or more of narrow and/or re-entrant openings, constrictions within the feature, and high aspect ratios. One example of a feature is a hole or via in a semiconductor substrate or a layer on the substrate. Another example is a trench in a substrate or layer. In various instances, the feature may have an under-layer, such as a barrier layer or adhesion layer. Non-limiting examples of under-layers include dielectric layers and conducting layers, e.g., silicon oxides, silicon nitrides, silicon carbides, metal oxides, metal nitrides, metal carbides, and metal layers.

While ALE methods have shown substantial promise, conventional chemistries used with such processes have exhibited a number of drawbacks. For instance, such chemistries can result in long processing times, with associated low throughput and high processing costs.

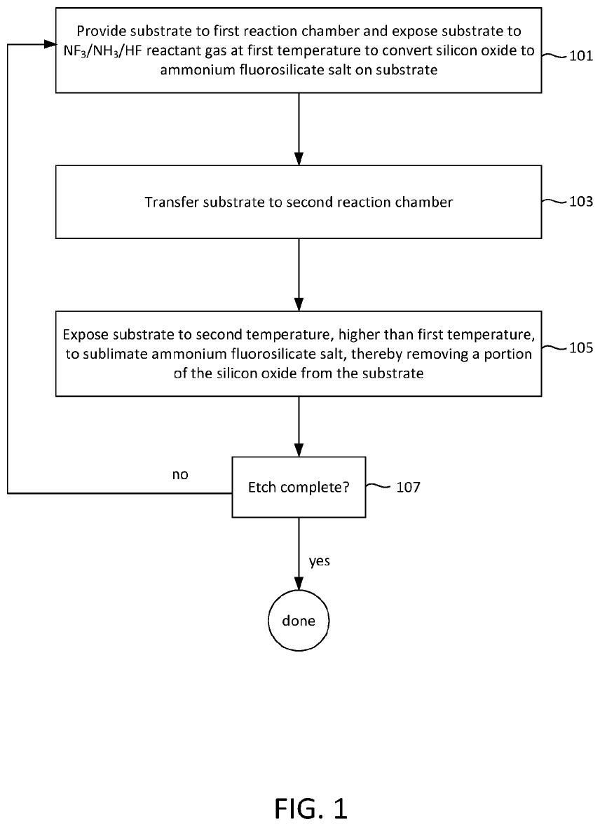

FIG. 1 provides a flowchart describing an ALE method where a reactant gas including NF₃/NH₃/HF is used. A substrate having silicon oxide exposed thereon is provided to a first reaction chamber. At operation 101, the substrate is exposed to a reactant gas including vapor phase NF₃/NH₃/HF in the first reaction chamber. These chemistries may be flowed in separately or together as desired for a particular application. In some examples, the reactant gas is provided as two streams, one of which includes NF₃/NH₃, and the other of which includes HF/NH₃. The reactant gas reacts with the silicon oxide on the surface of the substrate to form an ammonium fluorosilicate salt (e.g., (NH₄)₂SiF₆). Operation 101 is performed at a first temperature, for example between about 30-40° C. Operation 101 corresponds to the modification operation described above.

Next, at operation 103 the substrate is transferred to a second reaction chamber. Then, at operation 105, the substrate is exposed to a second temperature in the second reaction chamber.

The second temperature in operation 105 is higher than the first temperature in operation 101. For example, the second temperature may be between about 120-150°° C. Exposure of the substrate to the second temperature encourages sublimation/removal of the ammonium fluorosilicate salt from the substrate. The substrate may also be exposed to a flow of inert gas (e.g., N₂, Ar, He, Ne, etc.) during operation 105 to further encourage removal of the fluorosilicate salt from the substrate and from the second reaction chamber.

At operation 107, it is determined whether the etching process is complete. This determination may be made based on metrology, timing, etc. If the etching process is complete, the method is finished after operation 107. However, if the etching process is not complete. the method cycles back to operation 101, where the substrate is transferred back to the first reaction chamber and exposed to the reactant gas to convert additional silicon oxide to ammonium fluorosilicate salt. The method continues to cycle until the etching process is complete.

In the example of FIG. 1, two different reaction chambers are used including a first reaction chamber for the modification step in operation 101 and a second reaction chamber for the removal step in operation 105. The use of two separate reaction chambers allows for each reaction chamber to be maintained at its desired operating temperature. For instance, the first reaction chamber may be maintained between about 30-40° C., and the second reaction chamber may be maintained between about 120-150°° C. One disadvantage of this approach is that it requires two reaction chambers, resulting in increased capital costs. Another disadvantage of this approach is that it takes time to transfer the substrate between reaction chambers, and the substrate may be vulnerable to damage during the transfer operations. A further disadvantage of the approach/chemistry described in relation to FIG. 1 is that it provides relatively low selectivity between silicon oxide and silicon nitride materials (e.g., a selectivity between about 3-6).

Some of these disadvantages can be avoided by using a single reaction chamber. However, it takes a substantial amount of processing time to achieve the desired temperature for each step. In many cases this heating or cooling time is longer than the time it would take to transfer the substrate between reaction chambers. As such, when the method of FIG. 1 is modified to be performed in a single reaction chamber, there is relatively low throughput and associated high processing costs.

In addition to cyclic etching approaches such as ALE, continuous etching methods have also been developed. In one example, a substrate having silicon oxide thereon is exposed to a reactant gas including vapor phase pyridine, isopropyl alcohol, and HF. The reactant gas forms an adsorbed layer on the surface of the substrate, reacting with exposed silicon oxide to remove it from the substrate in a continuous manner (e.g., without formation of a salt). The etching may be done at a temperature between about 70-150° C. The etching may be done without substantially varying the temperature of the substrate support/reaction chamber. Generally, tuning the etch process at relatively lower temperatures results in much faster oxide etch rates, providing high throughput and efficiency. This continuous etch process also shows good etch selectivity, for example with silicon oxide: silicon nitride etch selectivity as high as about 50:1. However, the chemistry used for this continuous etch process can be sensitive to variations in the density of the silicon oxide that is being removed. As such, when the substrate includes oxide materials having differing densities, the etch results may be very uneven across the substrate (e.g., with more substantial etching where the oxide is less dense, and less substantial etching where the oxide is more dense). This non-uniformity is often undesirable.

### Etching Methods

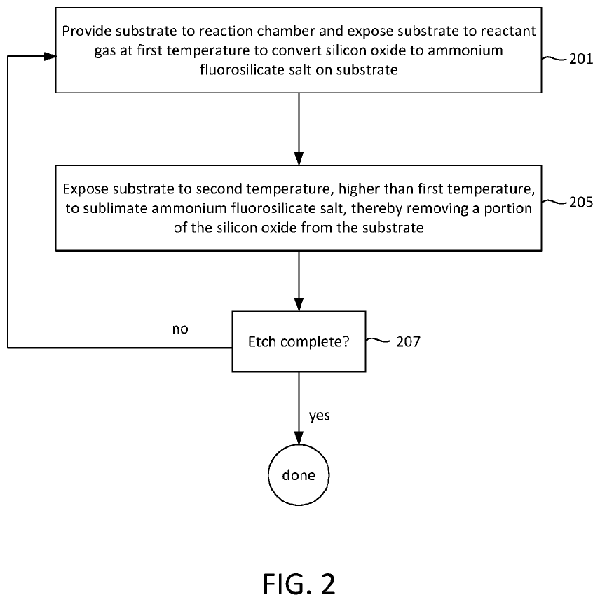

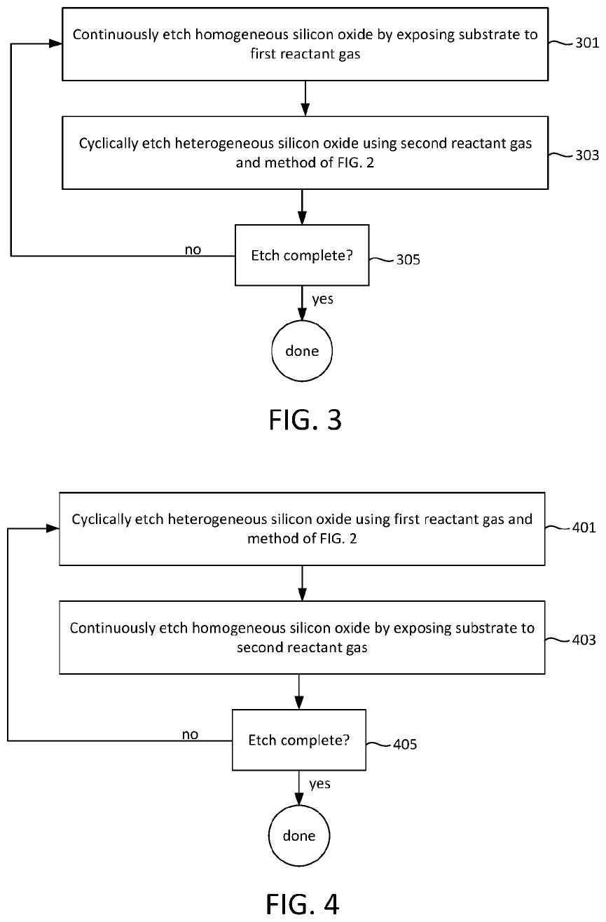

The various disadvantages discussed above can be avoided by using an alternative chemistry. This chemistry may be used in a new cyclic process similar to the method described above in FIG. 1. The new cyclic process is presented in FIG. 2. In some cases, the new cyclic process may be combined with the continuous etching process described above, as discussed further below in relation to FIGS. 3 and 4.

FIG. 2 presents a method of etching a substrate according to various embodiments herein. The method begins with operation 201, where the substrate is provided to a reaction chamber and exposed to a reactant gas to convert exposed silicon oxide on the substrate to a thin layer of ammonium fluorosilicate salt. The reactant gas includes (i) an ammonium-based hydroxide vapor; (ii) solvent; and (iii) a fluorine-source vapor.

The ammonium-based hydroxide vapor is generated from one or more ammonium-based hydroxide source. Example ammonium-based hydroxide sources include, but are not limited to, ammonium hydroxide (NH₄OH) and substituted forms of ammonium hydroxide. Substitutions may include one or more aliphatic or aromatic group, e.g., having CₓH_{y}-containing functional groups. Particular examples of substituted forms of ammonium hydroxide include, but are not limited to, alkyl-substituted ammonium hydroxides such as tetramethylammonium hydroxide, tetraethylammonium hydroxide, tetrapropyl ammonium hydroxide, etc. In various embodiments, the substituted ammonium hydroxide is fully substituted, e.g., having four functional groups (other than H) attached to the N. Fewer substitutions may be made in other examples.

Ammonium hydroxide forms when ammonia dissolves in water. As such, a combination of ammonia in water, or a substituted form of ammonia in water, may also act as the ammonium-based hydroxide source. The ammonia may be substituted in a similar way as described above with respect to the ammonium hydroxide.

The ammonium-based hydroxide and solvent may be provided as a solution that is vaporized prior to delivery to the reaction chamber. Ammonium hydroxide is commonly available in a solution having about 30% NH₄OH and about 70% H₂O. Solutions of other concentrations or compositions can be made as desired for particular applications.

In many examples, the solvent is water. However, the invention is not so limited. Examples of other solvents that may be used include, but are not limited to, acetone, acetonitrile, alcohols (e.g, methanol, ethanol, propanol, butanol, pentanol, etc.), chloroform, dichlorobenzene, dichloroethane, dimethylacetamide, dimethylformamide, dimethylsulfoxide, formamide, hexamethylphosphoramide, nitrobenzene, nitromethane, pyridine, etc. In many cases, the solvent is polar. In various examples, the solvent may have a dielectric constant that is at least as high as chloroform, or at least as high as ethanol. Two or more solvents may be used in some examples.

In some examples, a solution that is vaporized to provide the ammonium-based hydroxide includes between about 1-40 wt % NH₄OH (or other ammonium-based hydroxide), for example between about 25-35 wt % ammonium-based hydroxide. In various examples, the solution includes at least about 1 wt % ammonium-based hydroxide, for example at least about 10 wt % ammonium-based hydroxide, or at least about 20 wt % ammonium-based hydroxide, or at least about 25 wt % ammonium hydroxide. In these or other examples, the solution may include a maximum of about 40 wt % ammonium-based hydroxide, for example a maximum of about 35 wt % ammonium-based hydroxide, or a maximum of about 30 wt % ammonium-based hydroxide, or a maximum of about 25 wt % ammonium-based hydroxide, or a maximum of about 20 wt % ammonium-based hydroxide. The remaining portion of the solution may be the water or other solvent. In addition to the ammonium-based hydroxide and solvent, the solution may include one or more carrier gases and/or additional chemistries as desired for a particular application. In some embodiments, additional solvent (e.g., water vapor or others) may be provided to the reaction chamber separately from the ammonium-based hydroxide solution. Example flow rates for the combined ammonium-based hydroxide vapors, solvent vapors, and carrier gas into the reaction chamber may be between about 100-500 sccm.

The fluorine source may be gaseous, or it may be a liquid that is vaporized prior to delivery to the reaction chamber. Various fluorine sources may be used, including but not limited to HF, F₂, etc. In various embodiments, the fluorine source does not include carbon. Example flow rates for the fluorine source may be between about 10 to 1000 sccm.

Operation 201 occurs at a first temperature. The first temperature may fall within a range having a minimum temperature and/or a maximum temperature. The minimum temperature may be about 50° C., about 60° C., about 70° C., about 80° C., about 90° C., or about 95° C. The maximum temperature may be about 70° C., about 80° C., about 90° C., about 100° C., about 110° C., or about 120° C. The pressure in the reaction chamber during the modification step may be between about 0.6 T to 5 T.

Experimental results, discussed further below, show that the disclosed chemistry can be used to form ammonium fluorosilicate salt at temperatures at least up to about 100° C. At the conditions tested, substantial salt formation occurred at temperatures lower than about 70° C.

Above about 70° C., salt formation and temperature were inversely proportional, with relatively little salt formation above about 100° C.

Returning to the embodiment of FIG. 2, the method continues with operation 205, where the substrate is exposed to a second temperature to sublimate the ammonium fluorosilicate salt, thereby removing a portion of the silicon oxide from the substrate.

The second temperature is higher than the first temperature. The second temperature may fall within a range having a minimum and/or a maximum. In various embodiments, the minimum temperature may be about 100° C., about 110° C., or about 120° C. In these or other embodiments, the maximum temperature may be about 120° C., about 130°° C., or about 150° C., or about 200° C. The pressure in the reaction chamber during the removal step may be between about 0.6 T to 5 T. During operation 205, the substrate may be exposed to a flow of inert gas (e.g., N₂, Ar, He, Ne, etc.) to promote removal of the fluorosilicate salt from the substrate and reaction chamber.

Next, at operation 207, it is determined whether the etching process is complete. If so, the method is complete. If not, the method cycles back to operation 201 and continues to cycle until etching is complete. This determination may be made based on metrology, timing, etc.

Notably, the method of FIG. 2 can be used to form ammonium fluorosilicate salt at substantially higher temperatures than those used in the method of FIG. 1, as discussed further below in the Experimental section. When practicing the method of FIG. 1 (e.g., where the reactant gas includes a mixture of NF₃/NH₃/HF), the modification step at operation 101 should be performed at a temperature between about 30-40° C. to ensure adequate salt formation. At higher temperatures, salt formation is substantially limited. The result is a large temperature differential between the modification step in operation 101 and the removal step in operation 105, since the removal operation needs to be performed at a relatively high temperature (typically above about 120° C.). As such, when practicing the method of FIG. 1, the temperature differential between the modification step in operation 101 and the removal step in operation 105 is typically at least about 80° C. This large temperature differential is problematic for the reasons discussed above.

By contrast, when practicing the method of FIG. 2, the modification step at operation 201 can be performed at a higher temperature (compared to operation 101 of FIG. 1). The resulting temperature differential between the modification step at operation 201 and the removal step at operation 205 in the method of FIG. 2 is substantially smaller than the temperature differential that occurs between the modification step at operation 101 and the removal step at operation 105 in the method of FIG. 1. In some embodiments, the temperature differential between operations 201 and 205 may be about 60° C. or less, about 50° C. or less, about 40° C. or less, about 30° C. or less, about 20° C. or less, or about 10° C. or less. This decrease in temperature differential compared to the method of FIG. 1 is highly advantageous for the reasons discussed above, including but not limited to faster processing times, eliminating the need to switch reaction chambers between modification and removal operations, increased throughput and efficiency, and decreased processing costs.

Further, the method of FIG. 2 has shown excellent results with respect to etch selectivity and uniformity of etch rate between oxide materials of differing density. For instance, at low temperatures the low density and high density oxide materials etch at very similar rates, nearly 1:1. At higher temperatures there is a greater difference, but even at high temperatures the etch rate ratio between low density: high density oxide materials is about 3:1 or less. In various embodiments, the etch rate ratio between low density: high density oxide materials when practicing the method of FIG. 2 is about 3:1 or less, for example about 2:1 or less, or about 1.5:1 or less, or about 1.2:1 or less. As this ratio approaches 1:1, the low density and high density oxide materials etch at the same rate.

In various examples, the ammonium-based hydroxide is ammonium hydroxide, the fluorine source is HF and/or F₂, and the ammonium fluorosilicate salt has a formula of (NH₄)₂SiF₆. Of course, some impurities may be present. The salt that forms may also have a different formula, for example when other ammonium-based hydroxides and/or fluorine sources are used. Such chemistries may include elements that may be incorporated into the salt.

FIGS. 3 and 4 present embodiments where the cyclic etching method of FIG. 2 is combined with a continuous etching method such as the one described above. These methods are particularly useful when the silicon oxide being removed includes one or more portion that is homogeneous with respect to oxide density and one or more portion that is heterogeneous with respect to oxide density. In various cases, silicon oxide that is heterogeneous with respect to oxide density includes a first area having a first oxide density and a second area having a second oxide density, where the first and second oxide densities are different. For instance, the first oxide density may be greater or less than the second oxide density by at least about 10%, or at least about 20%, or at least about 30%. The first and second areas may be simultaneously exposed on the substrate surface.

Because the cyclic etching method of FIG. 2 is not sensitive to differences in oxide density, it is particularly useful for etching processes in which the oxide being removed is heterogeneous with respect to density. By contrast, the continuous etching method described above is sensitive to differences in oxide density, which makes it less useful for etching processes in which the oxide being removed is heterogeneous with respect to density. However, the continuous etching process is very fast. As such, it is useful for etching processes in which the oxide being removed is homogeneous with respect to density. In the methods of FIGS. 3 and 4, the cyclic and continuous etching processes are combined to tailor the etch conditions based on whether the oxide being removed at a particular point in time is homogeneous or heterogeneous with respect to density. This strategy provides highly uniform etch results, even with relatively short processing times.

In the method of FIG. 3, the substrate includes at least one portion of silicon oxide that is homogeneous with respect to oxide density and at least one portion of silicon oxide that is heterogeneous with respect to oxide density. When the method begins, the silicon oxide exposed on the substrate surface is homogeneous with respect to oxide density. The method begins with operation 301, where the homogeneous silicon oxide is etched using a continuous process that uses a first reactant gas. In a particular example, the first reactant gas includes HF, pyridine, and isopropyl alcohol, as discussed above. Other halogen sources, solvents, and/or additives may be used in other embodiments, provided that they result in substantially continuous etching.

Next, at operation 303, the heterogeneous silicon oxide is etched using the cyclic process described in FIG. 2. The cyclic etching is done using a second reactant gas. The second reactant gas may have a composition as described above in relation to operation 201 of FIG. 2. All other details provided in relation to FIG. 2 may apply here.

At operation 305, it is determined whether the etching process is complete. If yes, the method is complete. If not, the method returns to operation 301, where an additional portion of homogeneous silicon oxide is etched in a continuous manner. The method continues to cycle until the etch is complete.

In the method of FIG. 4, the substrate includes at least one portion of silicon oxide that is heterogeneous with respect to oxide density and at least one portion of silicon oxide that is homogeneous with respect to oxide density. When the method begins, the silicon oxide exposed on the substrate surface is heterogeneous with respect to oxide density. The method of FIG. 4 begins with operation 401, where the heterogeneous silicon oxide is etched using a first reactant gas and the process described in relation to FIG. 2.

Next, at operation 403, the homogeneous silicon oxide is etched using a second reactant gas and the continuous etching process described above. In a particular example, the second reactant gas includes HF, pyridine, and isopropyl alcohol, as discussed above. Other halogen sources, solvents, and/or additives may be used in other embodiments, provided that they result in substantially continuous etching.

The methods of FIGS. 3 and 4 incorporate the method of FIG. 2. Any details provided above in relation to FIG. 2 may also apply to relevant portions of FIGS. 3 and 4. For the sake of brevity, such details will not be repeated.

### APPARATUS

### Apparatuses for Thermal Processing

Provided herein are methods and apparatuses for semiconductor processing, for example to etch a semiconductor substrate using thermal energy, rather than or in addition to plasma energy. In certain embodiments, etching that relies upon chemical reactions in conjunction with primarily thermal energy, not a plasma, to drive the chemical reactions may be considered “thermal etching”. In various embodiments, apparatuses described herein are designed or configured to rapidly heat and cool a substrate, and precisely control a substrate's temperature. In some embodiments, the substrate is rapidly heated and its temperature is precisely controlled using, in part, visible light emitted from light emitting diodes (LEDs) positioned in a pedestal under the substrate. The visible light may have wavelengths that include and range between 400 nanometers (nm) and 800 nm. The pedestal may include various features for enabling substrate temperature control, such as a transparent window that may have lensing for advantageously directing or focusing the emitted light, reflective material also for advantageously directing or focusing the emitted light, and temperature control elements that assist with temperature control of the LEDs, the pedestal, and the chamber.

The apparatuses may also thermally isolate, or thermally “float,” the substrate within the processing chamber so that only the smallest thermal mass is heated, the ideal smallest thermal mass being just the substrate itself, which enables faster heating and cooling. The substrate may be rapidly cooled using a cooling gas and radiative heat transfer to a heat sink, such as a top plate (or other gas distribution element) above the substrate, or both. In some instances, the apparatus also includes temperature control elements within the processing chamber walls, pedestal, and top plate (or other gas distribution element), to enable further temperature control of the substrate and processing conditions within the chamber, such the prevention of unwanted condensation of processing gases and vapors.

The apparatuses may also be configured to implement various control loops to precisely control the substrate and the chamber temperatures (e.g., with a controller configured to execute instructions that cause the apparatus to perform these loops). This may include the use of various sensors that determine substrate and chamber temperatures as part of open loops and feedback control loops. These sensors may include temperature sensors in the substrate supports which contact the substrate and measure its temperature, and non-contact sensors such as photodetectors to measure light output of the LEDs and a pyrometer configured to measure the temperature of different types of substrates. As described in more detail below, some pyrometers determine an item's temperature by emitting infrared or other optical signals at the item and measuring the signals reflected or emitted by the item. However, many silicon substrates cannot be measured by some pyrometers because the silicon can be optically transparent at various temperatures and with various treatments, e.g., doped or low doped silicon. For example, a low doped silicon substrate at a temperature less than 200° C. is transparent to infrared signals. The pyrometers provided herein are able to measure multiple types of silicon substrates at various temperatures.

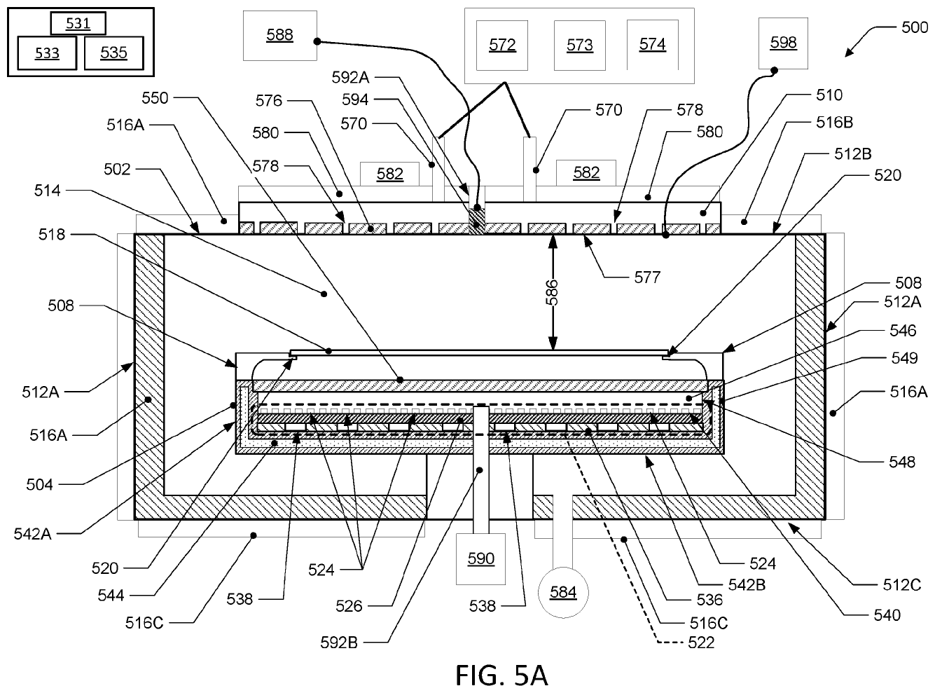

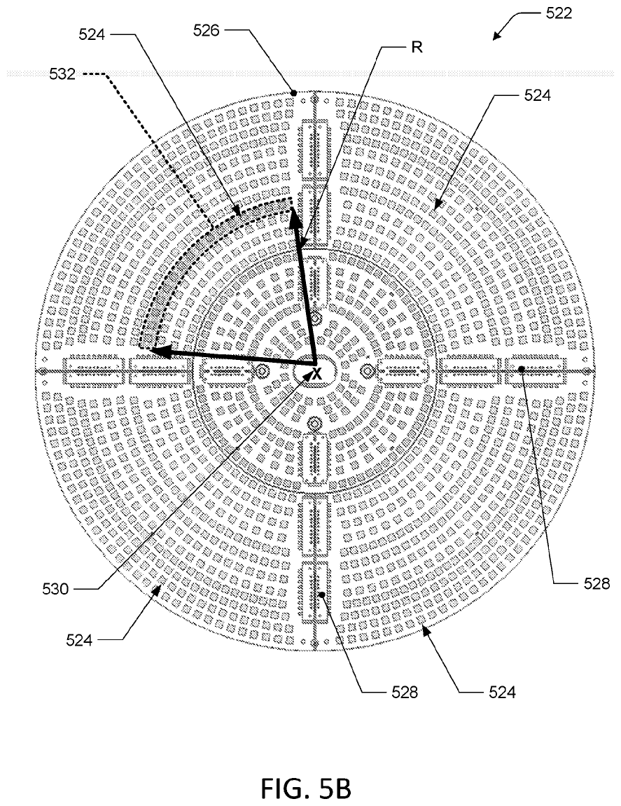

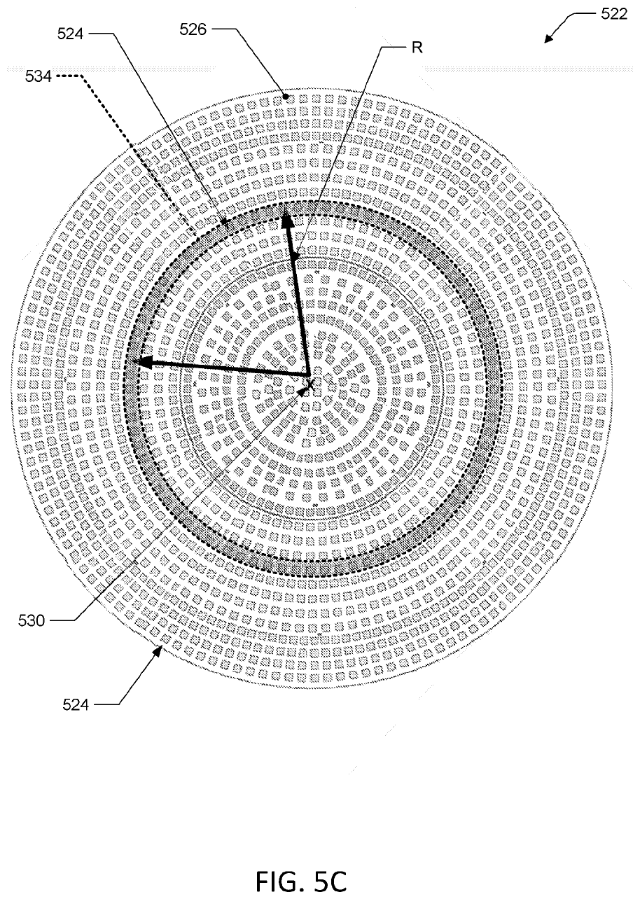

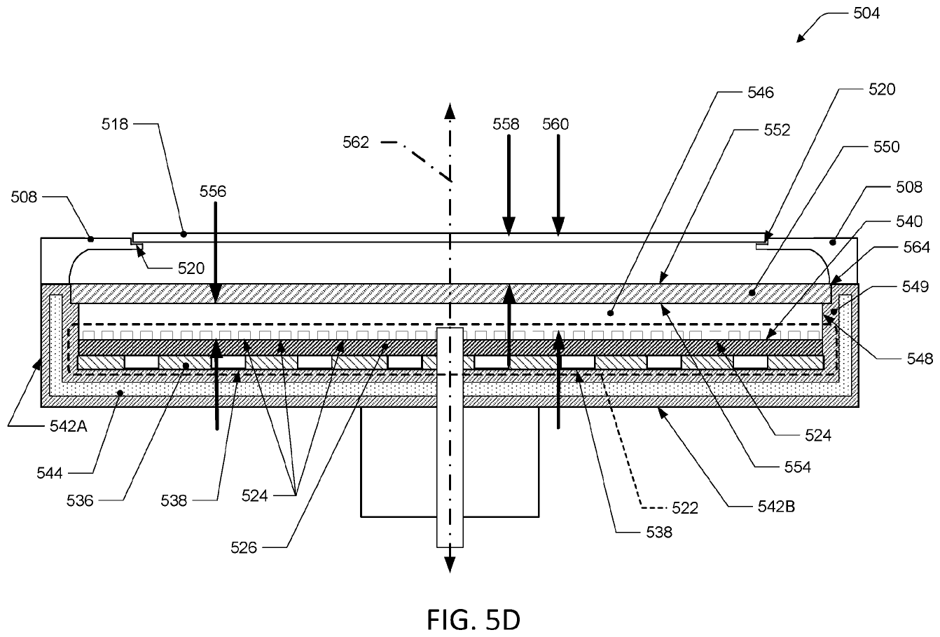

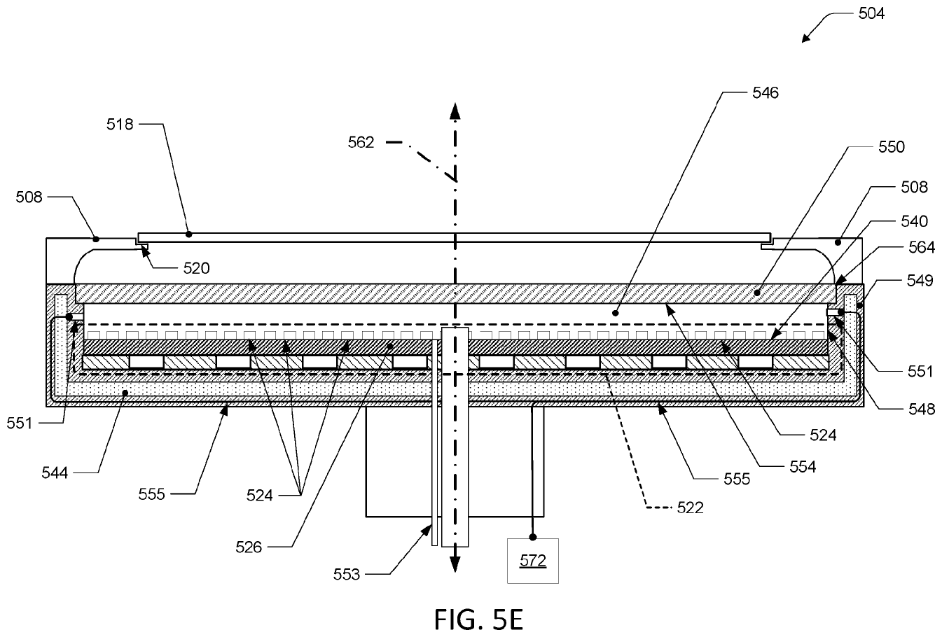

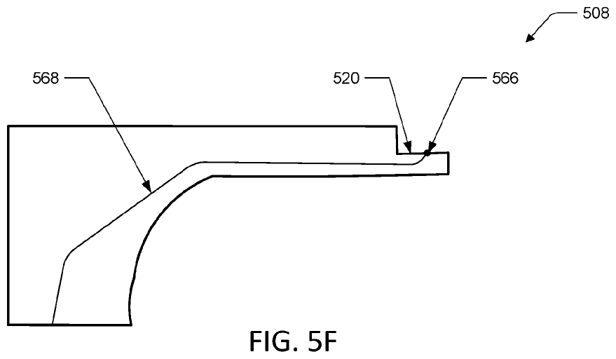

FIG. 5A depicts a cross-sectional side view of an example apparatus in accordance with disclosed embodiments. As detailed below, this apparatus 500 is capable of rapidly and precisely controlling the temperature of a substrate, including performing thermal etching operations. The apparatus 500 includes a processing chamber 502, a pedestal 504 having a substrate heater 506 and a plurality of substrate supports 508 configured to support a substrate 518, and a gas distribution unit 510.

The processing chamber 502 includes sides walls 512A, a top 512B, and a bottom 512C, that at least partially define the chamber interior 514, which may be considered a plenum volume. As stated herein, it may be desirable in some embodiments to actively control the temperature of the processing chamber walls 512A, top 512B, and bottom 512C in order to prevent unwanted condensation on their surfaces. Some emerging semiconductor processing operations flow vapors, such as water and/or alcohol vapor, onto the substrate which adsorb onto the substrate, but they may also undesirably adsorb onto the chamber's interior surfaces. This can lead to unwanted deposition and etching on the chamber interior surfaces which can damage the chamber surfaces and cause particulates to flake off onto the substrate thereby causing substrate defects. In order to reduce and prevent unwanted condensation on the chamber's interior surfaces, the temperature of chamber's walls, top, and bottom may be maintained at a temperature at which condensation of chemistries used in the processing operations does not occur.

This active temperature control of the chamber's surfaces may be achieved by using heaters to heat the chamber walls 512A, the top 512B, and the bottom 512C. As illustrated in FIG. 5A, chamber heaters 516A are positioned on and configured to heat the chamber walls 512A, chamber heaters 516B are positioned on and configured to heat the top 512B, and chamber heaters 516C are positioned on and configured to heat the bottom 512C. The chamber heaters 516A-516C may be resistive heaters that are configured to generate heat when an electrical current is flowed through a resistive element. Chamber heaters 516A-516C may also be fluid conduits through which a heat transfer fluid may be flowed, such as a heating fluid which may include heated water. In some instances, the chamber heaters 516A-516C may be a combination of both heating fluid and resistive heaters. The chamber heaters 516A-516C are configured to generate heat in order to cause the interior surfaces of each of the chamber walls 512A, the top 512B, and the bottom 512C to the desired temperature, which may range between about 40° C. and about 150° C., including between about 80° C. and about 130° C., about 90° C. or about 120° C., for instance. It has been discovered that under some conditions, water and alcohol vapors do not condense on surfaces kept at about 90° C. or higher.

The chamber walls 512A, top 512B, and bottom 512C, may also be comprised of various materials that can withstand the chemistries used in the processing techniques. These chamber materials may include, for example, an aluminum, anodized aluminum, aluminum with a polymer, such as a plastic, a metal or metal alloy with a yttria coating, a metal or metal alloy with a zirconia coating, and a metal or metal alloy with aluminum oxide coating; in some instances the materials of the coatings may be blended or layers of differing material combinations, such as alternating layers of aluminum oxide and yttria, or aluminum oxide and zirconia. These materials are configured to withstand the chemistries used in the processing techniques, such as ammonium-based hydroxides, anyhydrous HF, water vapor, methanol, isopropyl alcohol, chlorine, fluorine gases, nitrogen gas, hydrogen gas, helium gas, and mixtures thereof.

The apparatus 500 may also be configured to perform processing operations at or near a vacuum, such as at a pressure of about 0.1 Torr to about 100 Torr, or about 20 Torr to about 200 Torr, or about 0.1 Torr to about 10 Torr. This may include a vacuum pump 584 configured to pump the chamber interior 514 to low pressures, such as a vacuum having a pressure of about 0.1 Torr to about 100 Torr, including about 0.1 Torr to about 10 Torr, and about 20 Torr to about 200 Torr, or about 0.1 Torr to about 10 Torr.

Various features of the pedestal 504 will now be discussed. The pedestal 504 includes a

heater 522 (encompassed by the dashed rectangle in FIG. 5A) that has a plurality of LEDs 524 that are configured to emit visible light having wavelengths including and between 400 nm to 800 nm, including 450 nm. The heater LEDs emit this visible light onto the backside of the substrate which heats the substrate. Visible light having wavelengths from about 400 nm to 800 nm is able to quickly and efficiently heat silicon substrates from ambient temperature, e.g., about 20° C., to temperatures as high as about 600° C. because silicon absorbs visible light within this range. In contrast, radiant heating, including infrared radiant heating, may ineffectively heat silicon at temperatures up to about 400° C. because silicon tends to be transparent to infrared at temperatures lower than about 400° C. Additionally, radiant heaters that directly heat the topside of a substrate, as in many conventional semiconductor processes, can cause damage or other adverse effects to the topside films. Many “hot plate” heaters that rely on solid-to-solid thermal transference between the substrate and a heating platen, such as a pedestal with a heating coil, have relatively slow to heating and cooling rates, and provide non-uniform heating which may be caused by substrate warping and inconsistent contact with the heating platen. For example, it may take multiple minutes to heat some pedestals to a desired temperature, and from a first to a second higher temperature, as well as to cool the pedestal to a lower temperature.

The heater's plurality of LEDs may be arranged, electrically connected, and electrically controlled in various manners. Each LED may be configured to emit a visible blue light and/or a visible white light. In certain embodiments, white light (produced using a range of wavelengths in the visible portion of the EM spectrum) is used. In some semiconductor processing operations, white light can reduce or prevent unwanted thin film interference. For instance, some substrates have backside films that reflect different light wavelengths in various amounts, thereby creating an uneven and potentially inefficient heating. Using white light can reduce this unwanted reflection variation by averaging out the thin film interference over the broad visible spectrum provided by white light. In some instances, depending on the material on the back face of the substrate, it may be advantageous to use a visible non-white light, such as a blue light having a 450 nm wavelength, for example, in order to provide a single or narrow band of wavelength which may provide more efficient, powerful, and direct heating of some substrates that may absorb the narrow band wavelength better than white light.

Various types of LED may be employed. Examples include a chip on board (COB) LED or a surface mounted diode (SMD) LED. For SMD LEDs, the LED chip may be fused to a printed circuit board (PCB) that may have multiple electrical contacts allowing for the control of each diode on the chip. For example, a single SMD chip may have three diodes (e.g., red, blue, or green) that can be individually controllable to create different colors, for instance. SMD LED chips may range in size, such as 2.8×2.5 mm, 3.0×3.0 mm, 3.5×2.8 mm, 5.0×5.0 mm, and 5.6×3.0 mm. For COB LEDs, each chip can have more than three diodes, such as nine, 12, tens, hundreds or more, printed on the same PCB. COB LED chips typically have one circuit and two contacts regardless of the number of diodes, thereby providing a simple design and efficient single color application. The ability and performance of LEDs to heat the substrate may be measured by the watts of heat emitted by each LED; these watts of heat may directly contribute to heating the substrate.

FIG. 5B depicts a top view of a substrate heater with a plurality LEDs. This substrate heater 522 includes a printed circuit board 526 and the plurality of LEDs 524, some of which are labeled; this depicted plurality includes approximately 1,300 LEDs. External connections 528 are connected by traces to provide power to the plurality of LEDs 524. As illustrated in FIG. 5B, the LEDs may be arranged along numerous arcs that are radially offset from the center 530 of the substrate heater 522 by different radiuses; in each arc, the LEDs may be equally spaced from each other. For example, one arc 532 is surrounded by a partially shaded dotted shape, includes 16 LEDs 524, and is a part of a circle with a radius R that extends around the center 530. The 16 LEDs 524 may be considered equally spaced from each other along this arc 532.

In some embodiments, the LEDs may also be arranged along circles around the center of the substrate heater. In some instances, some LEDs may be arranged along circles while others may be arranged along arcs. FIG. 5C depicts a top view of another example of a substrate heater with a plurality LEDs. The substrate heater 522 of FIG. 5C includes a printed circuit board 526 and the plurality of LEDs 524, some of which are labeled. Here, LEDs 524 are arranged along numerous circles that are radially offset from the center 530 of the substrate heater 522 by different radiuses; in each circle, the LEDs may be equally spaced from each other. For example, one circle 534 is surrounded by a partially shaded ring, includes 78 LEDs 524, and has a radius R that extends around the center 530. The 78 LEDs 524 may be considered equally spaced from each other along this circle 534. The arrangement of the LEDs in FIG. 5C may provide a more uniform light and heat distribution pattern across the entire backside of the substrate compared to the arrangement in FIG. 5B because the regions of the substrate heater 522 in FIG. 5B that contain the external connections may provide unheated cold spots on the substrate, especially because the substrate and heater remain stationary with respect to each other during processing; the substrate and the substrate heater do not rotate.

In some embodiments, the plurality of LEDs may include at least about 1,000 LEDs, including about 1,200, 1,500, 2,000, 3,000, 4,000, 5,000, or more than 6,000, for instance. Each LED may, in some instances, be configured to uses about 4 watts or less at 100% power, including about 3 watts at 100% power and about 1 watt at 100% power. These LEDs may be arranged and electrically connected into individually controllable zones to enable temperature adjustment and fine tuning across the substrate. In some instances, the LEDs may be grouped into at least 20, for instance, independently controllable zones, including at least about 25, 50, 75, 80, 85 90, 95, or 100 zones, for instance. These zones may allow for temperature adjustments in the radial and azimuthal (i.e., angular) directions. These zones can be arranged in a defined pattern, such as a rectangular grid, a hexagonal grid, or other suitable pattern for generating a temperature profile as desired. The zones may also have varying shapes, such as square, trapezoidal, rectangular, triangular, obround, elliptical, circular, annular (e.g., a ring), partially annular (e.g., an annular sector), an arc, a segment, and a sector that may be centered on the center of the heater and have a radius less than or equal to the overall radius of the substrate heater's PCB. For example, in FIG. 5B the LEDs have 88 zones that are organized into at least 20, such as 20 or 21, concentric rings. These zones are able to adjust the temperature at numerous locations across the substrate in order to create a more even temperature distribution as well as desired temperature profiles, such as higher temperatures around the edge of the substrate than in the center of the substrate. The independent control of these zones may also include the ability to control the power output of each zone. For example, each zone may have at least 15, 20, or 25 adjustable power outputs. In some instances, each zone may have one LED thereby enabling each LED to be individually controlled and adjusted which can lead to a more uniform heating profile on the substrate. Accordingly, in some embodiments, each LED of the plurality of LEDs in the substrate heater may be individually controllable.

In certain embodiments, the substrate heater 522 is configured to heat the substrate to multiple temperatures and maintain each such temperature for various durations. The substrate heater may be configured to heat the substrate to between about 50° C. and 600° C., including to any temperature or range between these temperatures. Additionally, in some embodiments, the substrate heater 522 is configured to heat the substrate to any temperature within these ranges in less than about 60 seconds, less than about 45 seconds, less than about 30 seconds, or less than about 15 seconds, for instance. In certain embodiments, the substrate heater 522 is configured to heat a substrate at one or more heating rates, such as between at least about 0.1° C./second and at least about 20° C./second, for example.

The substrate heater may increase the temperature of the substrate by causing the LEDs to emit the visible light at one or more power levels, including at least about 80%, at least about 90%, at least about 95%, or at least about 100% power. In some embodiments, the substrate heater is configured to emit light between about 10 W and 4000 W, including at least about 10 W, at least about 30 W, at least about 0.3 kilowatt (kW). at least about 0.5 kW, at least about 2 kW, at least about 3 kW, or at least about 4kw. The apparatus is configured to supply between about 0.1 kw and 9 kW of power to the pedestal; the power supply is connected to the substrate heater through the pedestal but is not depicted in the Figures. During temperature ramps, the substrate heater may operate at the high powers, and may operate at the lower power levels (e.g., including between about 5 W and about 0.5 kW) to maintain the temperature of a heated substrate.

The pedestal may include reflective material on its internal surfaces that, during operation, reflects and directs the light emitted by the LEDs onto the backside of the substrate supported by the pedestal. In some such embodiments, the substrate heater may include such reflective material positioned on a top surface 540, as shown in FIG. 5A, of the PCB 526 on which the plurality of LEDs 524 is positioned. The reflective material may be comprised of aluminum, such as polished aluminum, stainless steel, aluminum alloys, nickel alloys, and other protective layers which can prevent oxidation of the metal and/or enhance the reflectivity at specific wavelengths, such as reaching greater than 99% reflectivity for specific wavelengths, and other durable reflective coatings. Additionally or alternatively, the pedestal 504 may have a bowl 546 in which the substrate heater 522 is at least partially positioned. The bowl 546 may have exposed internal surfaces 548 of the pedestal sidewalls 549 upon which the reflective material may be positioned. This reflective material increases the heating efficiency of the substrate heater and reduces the unwanted heating of the PCB 526 and pedestal 504 by advantageously directing light back onto the substrate that would have otherwise been absorbed by the PCB 526 and the pedestal 504.

In some embodiments, the substrate heater may also include a pedestal cooler that is thermally connected to the LEDs such that heat generated by the plurality of LEDs can be transferred from the LEDs to the pedestal cooler. This thermal connection is such that heat can be conducted from the plurality of LEDs to the pedestal cooler along one or more heat flow pathways between these components. In some instances, the pedestal cooler is in direct contact with one or more elements of the substrate heater, while in other instances other conductive elements, such as thermally conductive plates (e.g., that comprise a metal) are interposed between the substrate heater and the pedestal cooler. Referring back to FIG. 5A, the substrate heater includes a pedestal cooler 536 in direct contact with the bottom of the PCB 526. Heat is configured to flow from the LEDs, to the PCB 526, and to the pedestal cooler 536. The pedestal cooler 536 also includes a plurality of fluid conduits 538 through which a heat transfer fluid, such as water, is configured to flow in order to receive the heat and thus cool the LEDs in the substrate heater 522. The fluid conduits 538 may be connected to a reservoir and pump, not pictured, located outside the chamber. In some instances, the pedestal cooler may be configured to flow water that is cooled, such as between about 5° C. and 20° C.

As provided herein, it may be advantageous to actively heat the exterior surfaces of the processing chamber 502. In some instances, it may similarly be advantageous to heat the exterior surfaces of the pedestal 504 in order to prevent unwanted condensation and deposition on its external surfaces. As illustrated in FIG. 5A, the pedestal 504 may further include a pedestal heater 544 inside of the pedestal 504 that is configured to heat the exterior surfaces of the pedestal 504, including its sides 542A and bottom 542B. The pedestal heater 544 may include one or more heating elements, such as one or more resistive heating elements and fluid conduits in which a heating fluid is configured to flow. In some instances, the pedestal cooler and the pedestal heater may both have fluid conduits that are fluidically connected to each other such that the same heat transfer fluid may flow in both the pedestal cooler and the pedestal heater. In these embodiments, the fluid may be heated to between 50° C. and 130° C. including about 90° C. and 120° C.

The pedestal may also include a window to protect the substrate heater, including the plurality of LEDs, from damage caused by exposure to the processing chemistries and pressures used during processing operations. As illustrated in FIG. 5A, the window 550 may be positioned above the substrate heater 522 and may be sealed to the sidewall 549 of the pedestal 504 in order to create a plenum volume within the pedestal that is fluidically isolated from the chamber interior. This plenum volume may also be considered the inside of the bowl 546. The window may be comprised of one or more materials that are optically transparent to the visible light emitted by LEDs, including light having wavelengths in the range of 400 nm to 800 nm. In some embodiments, this material may be quartz, sapphire, quartz with a sapphire coating, or calcium fluoride (CaF). The window may also not have any holes or openings within it. In some embodiments, the heater may have a thickness of about 15 to 30 mm, including about 20 mm and about 25 mm.

FIG. 5D depicts the pedestal of FIG. 5A with additional features in accordance with various embodiments. As identified in FIG. 5D, the window 550 includes a top surface 552 that faces the substrate 518 supported by the pedestal 504, and a bottom surface 554 that faces the substrate heater 522. In some embodiments, the top and the bottom surfaces 552 and 554 may be flat, planar surfaces (or substantially flat, e.g., within +10% or 5% of flat). In some other instances, the top 552, bottom 554, or both top 552 and bottom 554 may be nonplanar surfaces. The nonplanarity of these surfaces may be configured to refract and/or direct the light emitted by the substrate heater's 522 LEDs 524 to more efficiently and/or effectively heat the substrate. The nonplanarity may also be along some or all of the surface. For example, the entire bottom surface may have a convex or concave curvature, while in another example an outer annular region of the bottom surface may have a convex or concave curvature while the remaining portion of the surface is planar. In further examples, these surfaces may have multiple, but different, nonplanar sections, such as having a conical section in the center of the surface that is adjacent to a planar annular section, that is adjacent to a conical frustum surface at the same or different angle as the conical section. In some embodiments, the window 550 may have features that act as an array of lenses which are oriented to focus the light emitted by one or more LEDs, such as each LED.

With the window 550 positioned above the substrate heater 522, the window 550 gets heated by the substrate heater 522 which can affect the thermal environment around the substrate. Depending on the material or materials used for the window 550, such as quartz, the window may retain heat and progressively retain more heat over the course of processing one or more substrates. This heat can get radiatively transferred to the substrate and therefore directly heat the substrate. In some instances, that the window can cause a temperature increase of between 50° C. and 80° C. above the heater temperature. This heat may also create a temperature gradient through the thickness, or in the vertical direction, of the window. In some instances, the top surface 552 is 30° C. hotter than the bottom surface 554. It may therefore be advantageous to adjust and configure the chamber to account for and reduce the thermal effects of the window. This may include detecting the substrate's temperature and adjusting the substrate heater to account for the heat retained by the window.

This may also include various configurations of the pedestal, such as actively cooling the window. In some embodiments, like that shown in FIGS. 5A and 5D, the window 550 may be offset from the substrate heater 522 by a first distance 556. In some embodiments, this first distance may be between about 2 mm and 50 mm, including between about 5 mm and 40 mm. A cooling fluid, such as an inert gas, may be flowed between the window 550 and the substrate heater 522 in order to cool both the window 550 and the substrate heater 522. The pedestal may have one or more inlets and one or more outlets for flowing this gas within the plenum volume, or bowl 546, of the pedestal 504. The one or more inlets are fluidically connected to the inert gas source outside the processing chamber 502, which may include through fluid conduits that may be at least partially routed inside the pedestal 504. The one or more outlets are fluidically connected to an exhaust or other environment outside the processing chamber 502, which may also be through fluid conduits running within the pedestal. In FIG. 5E, which depicts the pedestal of FIG. 5D with additional features in accordance with various embodiments, one or more inlets 551 are positioned in the sidewalls 549 and extend through the internal surface 548; the one or more inlets are also fluidically connected to a gas source 572 (e.g., an inert gas source) through, in part, fluid conduits 555 that are routed through the pedestal 504. A single outlet 553 is positioned in a center region, i.e., not in the exact center but in close proximity, of the substrate heater 522. In some embodiments, the one or more gas inlets and one or more outlets may be switched, such that the one or more outlets extend through the sidewalls 549 (i.e.., they are items 551 in FIG. 5E), and the one or more inlets may be the center region of the substrate heater 522 (i.e., they are item 553 in FIG. 5E). In some embodiments, there may be more than one outlet; in some embodiments, there may only be a single gas inlet. In some embodiments, one or more gas inlets extend through the internal surface 548 of the pedestal sidewall 549 underneath the LED heater 522 and one or more gas outlets extend through another part of the pedestal sidewall 549, such as a mounting bracket between the LED heater 522 and the pedestal sidewall 549.

In some embodiments, the window may be placed in direct, thermal contact with the substrate heater and the pedestal cooler may be configured to cool both the PCB and the window. In some embodiments, as also shown in FIGS. 5A and 5D, the window 550 may be thermally connected to the sidewalls 549 of the pedestal 504 in order to transfer some of the retained heat in the window 550 to the pedestal 504. This transferred heat may be further transferred out of the pedestal using, for instance, the pedestal heater 544 which may flow fluid through the pedestal 504 that is heated to between about 20° C. and 100° C., for instance. This heated fluid may be cooler than the temperature of the pedestal 504 at the thermal connection with the window 550. In some embodiments, the window 550 may have one or more fluid conduits within the window 550 through which transparent cooling fluid may be configured to flow. The fluid may be routed to the window through the pedestal from a fluid source or reservoir outside the chamber.

As shown in FIGS. 5A and 5D, the pedestal's 504 substrate supports 508 are configured to support the substrate 518 above and offset from the window 550 and the substrate heater 522. In certain embodiments, the temperature of the substrate can be rapidly and precisely controlled by thermally floating, or thermally isolating, the substrate within the chamber. It is desirable to position the substrate so that the smallest thermal mass is heated and cooled. This thermal floating is configured to position the substrate so that it has minimal thermal contact (which includes direct and radiation) with other bodies in the chamber.

The pedestal 504 is therefore configured, in some embodiments, to support the substrate 518 by thermally floating, or thermally isolating, the substrate within the chamber interior 514. The pedestal's 504 plurality of substrate supports 508 are configured to support the substrate 518 such that the thermal mass of the substrate 518 is reduced as much as possible to the thermal mass of just the substrate 518. Each substrate support 508 may have a substrate support surface 520 that provides minimal contact with the substrate 518. The number of substrate supports 508 may range from at least 3 to, for example, at least 6 or more. The surface area of the support surfaces 520 may also be the minimum area required to adequately support the substrate during processing operations (e.g., in order to support the weight of the substrate and prevent inelastic deformation of the substrate).

The substrate supports are also configured to prevent the substrate from being in contact with other elements of the pedestal, including the pedestal's surfaces and features underneath the substrate. As seen in FIGS. 5A and 5D, the substrate supports 508 hold the substrate 518 above and offset from the next adjacent surface of the pedestal 504 below the substrate 518, which is the top surface 552 (identified in FIG. 5D) of the window 550. As can be seen in these Figures, a volume or gap exists underneath the substrate, except for the contact with the substrate supports. As illustrated in FIG. 5D, the substrate 518 is offset from the top surface 552 of the window 550 by a distance 558. This distance 558 may affect the thermal effects caused by the window 550 to the substrate 518. The larger the distance 558, the less the effects. It was found that a distance 558 of 2 mm or less resulted in a significant thermal coupling between the window and the substrate; it is therefore desirable to have a larger distance 558 than 2 mm, such as at least about 5 mm, about 10 mm, about 15 mm, about 20 mm, about 30 mm, about 50 mm, or about 100 mm, for example.

The substrate 518 is also offset from the substrate heater 522 (as measured in some instances from a top surface of the substrate heater 522 which may be the top surface of the LEDs 524) by a distance 560. This distance 560 affects numerous aspects of heating the substrate 518. In some embodiments, a distance 560 of between about 10 mm and 90 mm, between about 5 mm and 100 mm, including between about 10 mm and 30 mm, for instance, provides a substantially uniform heating pattern and acceptable heating efficiency.

As stated, the substrate supports 508 are configured to support the substrate 518 above the window. In some embodiments, these substrate supports are stationary and fixed in position; they are not lift pins or a support ring. In some embodiments, at least a part of each substrate support 508 that includes the support surface 520 may be comprised of a material that is transparent at least to light emitted by LEDS 524. This material may be, in some instances, quartz or sapphire. The transparency of these substrate supports 508 may enable the visible light emitted by the substrate heater's 522 LEDs to pass through the substrate support 508 and to the substrate 518 so that the substrate support 508 does not block this light and the substrate 518 can be heated in the areas where it is supported. This may provide a more uniform heating of the substrate 518 than with a substrate support comprising a material opaque to visible light. In some other embodiments, the substrate supports 508 may be comprised of a non-transparent material, such as zirconium dioxide (ZrO₂).

In some embodiments, such as those shown in FIG. 5D, the substrate supports 508 may be positioned closer to a center axis 562 of the window than the outer diameter 564 of the window 550. In some instances, portions of these substrate supports may extend over and above the window 550.

In some embodiments, the substrate supports may each contain a temperature sensor that is configured to detect the temperature of the substrate positioned on the support surface of the substrate supports. FIG. 5F depicts a substrate support of FIGS. 5A and 5D in accordance with disclosed embodiments. Here, the support surface 520 of the substrate support 508 is identified, along with a temperature sensor 566. In some embodiments, this temperature sensor 566 extends through the support surface 520 such that the temperature sensor 566 is in direct contact with a substrate held by the support surface 520. In some other embodiments, the temperature sensor 566 is positioned within the substrate support 508 and below the support surface 520. In some embodiments, this temperature sensor 566 is a thermocouple. In some other embodiments, the temperature sensor 566 may be a thermistor, a resistance temperature detector (RTD), and semiconductor sensor. The electrical wiring 568 for the temperature sensor 566 may be routed through the substrate support 508 and may also be routed through the pedestal 504.

Referring back to FIG. 5A, in some embodiments, the pedestal is also configured to move vertically. This may include moving the pedestal such that a gap 586 between a faceplate 576 of the gas distribution unit 510 and the substrate 518 is capable of being in a range between about 2 mm and 70 mm. Moving the pedestal vertically may enable active cooling of the substrate as well as rapid cycling time of processing operations, including flowing gas and purging, due to a low volume created between the gas distribution unit 510 and the substrate 518. This movement may also enable the creation of a small process volume between the substrate and the gas distribution unit which can result in a smaller purge and process volumes and thus reduce purge and gas movement times and increase throughput.

The gas distribution unit 510 is configured to flow process gases, which may include liquids and/or gases, such as a reactant, modifying molecules, converting molecules, or removal molecules, onto the substrate 518 in the chamber interior 514. As seen in FIG. 5A, the gas distribution unit 510 includes one or more fluid inlets 570 that are fluidically connected to one or more gas sources 572 and/or one or more vapor sources 574. In some embodiments, the gas lines and mixing chamber may be heated to prevent unwanted condensation of the vapors and gases flowing within. These lines may be heated to at least about 40° C., at least about 80° C., at least about 90° C., at least about 120° C., at least about 130° C., or at least about 150° C. The one or more vapor sources may include one or more sources of gas and/or liquid which is vaporized. The vaporizing may be a direct inject vaporizer, a flow over vaporizer, or both. The gas distribution unit 510 also includes the faceplate 576 that includes a plurality of through-holes 578 that fluidically connect the gas distribution unit 510 with the chamber interior 514. These through-holes 578 are fluidically connected to the one or more fluid inlets 570 and also extend through a front surface 577 of the faceplate 576, with the front surface 577 configured to face the substrate 518. In some embodiments, the gas distribution unit 510 may be considered a top plate and in some other embodiments, it may be considered a showerhead.

The through-holes 578 may be configured in various ways in order to deliver uniform gas flow onto the substrate. In some embodiments, these through-holes may all have the same outer diameter, such as between about 0.03 inches and 0.05 inches, including about 0.04 inches (1.016 mm). These faceplate through-holes may also be arranged throughout the faceplate in order to create uniform flow out of the faceplate.

Referring back to FIG. 5A, the gas distribution unit 510 may also include a unit heater 580 that is thermally connected to the faceplate 576 such that heat can be transferred between the faceplate 576 and the unit heater 580. The unit heater 580 may include fluid conduits in which a heat transfer fluid may be flowed. Similar to above, the heat transfer fluid may be heated to a temperature range of about 20° C. and 120° C., for example. In some instances, the unit heater 580 may be used to heat the gas distribution unit 510 to prevent unwanted condensation of vapors and gases; in some such instances, this temperature may be at least about 90° C. or 120° C.

In some embodiments, the gas distribution unit 510 may include a second unit heater 582 that is configured to heat the faceplate 576. This second unit heater 582 may include one or more resistive heating elements, fluid conduits for flowing a heating fluid, or both. Using two unit heaters 580 and 582 in the gas distribution unit 510 may enable various heat transfers within the gas distribution unit 510. This may include using the first and/or second unit heaters 580 and 582 to heat the faceplate 576 in order to provide a temperature-controlled chamber, as described above, in order to reduce or prevent unwanted condensation on elements of the gas distribution unit 510.

The apparatus 500 may also be configured to cool the substrate. This cooling may include flowing a cooling gas onto the substrate, moving the substrate close to the faceplate to allow heat transfer between the substrate and the faceplate, or both. Actively cooling the substrate enables more precise temperature control and faster transitions between temperatures which reduces processing time and improves throughput. In some embodiments, the first unit heater 580 that flows the heat transfer fluid through fluid conduits may be used to cool the substrate 518 by transferring heat away from the faceplate 576 that is transferred from the substrate 518. A substrate 518 may therefore be cooled by positioning it in close proximity to the faceplate 576, such as by a gap 586 of less than or equal to 5 mm or 2 mm, such that the heat in the substrate 518 is radiatively transferred to the faceplate 576, and transferred away from the faceplate 576 by the heat transfer fluid in the first unit heater 580. The faceplate 576 may therefore be considered a heat sink for the substrate 518 in order to cool the substrate 518.

In some embodiments, the apparatus 500 may further include a cooling fluid source 573, which may contain a cooling fluid (a gas or a liquid), and a cooler (not pictured) configured to cool the cooling fluid to a desired temperature, such as less than or equal to about 90° C., less than or equal to about 70° C., less than or equal to about 50° C., less than or equal to about 20° C., less than or equal to about 10° C., less than or equal to about 0° C. less than or equal to about −50° C., less than or equal to about −100° C., less than or equal to about −150° C., less than or equal to about −190° C., about −200° C., or less than or equal to about −250° C., for instance. The apparatus 500 includes piping to deliver the cooling fluid to the one or more fluid inlets 570, and the gas distribution unit 510 which is configured to flow the cooling fluid onto the substrate. In some embodiments, the fluid may be in liquid state when it is flowed to the processing chamber 502 and may turn to a vapor state when it reaches the chamber interior 514, for example if the chamber interior 514 is at a low pressure state, such as described above, e.g., between about 0.1 Torr and 10 Torr, or between about 0.1 Torr and 100 Torr, or between about 20 Torr and 200 Torr, for instance. The cooling fluid may be an inert element, such as nitrogen, argon, or helium. In some instances, the cooling fluid may include, or may only have, a non-inert element or mixture, such as hydrogen gas. In certain embodiments, the apparatus may be configured to cool a substrate at one or more cooling rates, such as at least about 5° C./second, at least about 10° C./second, at least about 15° C./second, at least about 20° C./second, at least about 30° C./second, or at least about 40° C./second.

In some embodiments, the apparatus 500 may actively cool the substrate by both moving the substrate close to the faceplate and flowing cooling gas onto the substrate. In some instances, the active cooling may be more effective by flowing the cooling gas while the substrate is in close proximity to the faceplate. The effectiveness of the cooling gas may also be dependent on the type of gas used.

In some embodiments, the apparatus 500 may include a mixing plenum for blending and/or conditioning process gases for delivery before reaching the fluid inlets 570. One or more mixing plenum inlet valves may control introduction of process gases to the mixing plenum. In some other embodiments, the gas distribution unit 510 may include one or more mixing plenums within the gas distribution unit 510. The gas distribution unit 510 may also include one or more annular flow paths fluidically connected to the through-holes 578 which may equally distribute the received fluid to the through-holes 578 in order to provide uniform flow onto the substrate.

The apparatus 500 may also include one or more additional non-contact sensors for detecting the temperature of the substrate. Such sensors may include improved pyrometers, for instance. Although conventional pyrometers are not able to detect certain substrates within particular temperature ranges, the pyrometer described herein overcomes these problems. For instance, the pyrometer is configured to detect multiple emission ranges in order to detect multiple types of substrates, e.g., doped, low doped, or not doped, at various temperature ranges. This includes a configuration to detect emission ranges of about 0.95 microns to about 1.1 microns, about 1 micron, about 1 to about 4 microns, and/or about 8 to 15 microns. The pyrometer is also configured to detect the temperature of a substrate at a shorter wavelength in order to differentiate the signal from the thermal noise of the chamber.

The pyrometer may include an emitter configured to emit infrared signals and a detector configured to receive emissions. Referring to FIG. 5A, the apparatus includes the pyrometer 588 having an emitter within the pyrometer 588 and a detector 590. The pyrometer may be configured to emit signals on one side of the substrate, either the top or the bottom, and configured to receive signals on the other side of the substrate. For instance, the emitter may emit signals on the top of the substrate and the detector is under the substrate and receives signals emitted through and under the substrate. The apparatus may therefore have at least a first port 592A on the top of the processing chamber 502, such as the port 592A through the center of the gas distribution unit 510, and a second port 592B through the pedestal 504 and substrate heater 522. The emitter in the pyrometer 588 may be connected to one of the ports 592A or 592B via a fiberoptic connection, such as the first port 592A as shown in FIG. 5A, and the detector is optically connected to the other port, such as the second port 592B in FIG. 5A. The first port 592A may include a port window 594 to seal the first port 592A from the chemistries within the chamber interior 514. The second port 592B is seen in FIG. 5A extending through the pedestal 504 and the substrate heater such that the emitter's emissions can pass through the substrate, through the window 550, into the second port 592B and to the detector 590 that may be positioned in the second port or optically connected to the second port through another fiberoptic connection (not shown). In some other embodiments, the emitter and the detector are flipped, such that the emitter emits through the second port 592B and the detector detects through the first port 592A.

The apparatus 500 may also include one or more optical sensors 598 to detect one or more metrics of the visible light emitted by the LEDs. In some embodiments, these optical sensors may be one or more photodetectors configured to detect the light and/or light intensity of the light emitted by the LEDs of the substrate heater. In FIG. 5A, a single optical sensor 598 is shown as connected to the chamber interior 514 via fiberoptic connection such that the optical sensor 598 is able to detect light emitted by the substrate heater 522. The optical sensor 598, and additional optical sensors, can be positioned in various locations in the top and sides, for instance, of the processing chamber 502 in order to detect the emitted light at various locations within the processing chamber 502. As discussed below, this may enable the measurement and adjustment of the substrate heater, such as the adjustment of one or more independently controllable zones of the LEDs. In some embodiments, there may be a plurality of optical sensors 598 arranged along a circle or multiple concentric circles in order to measure various regions of the LEDs throughout the processing chamber 502. In some embodiments, the optical sensors may be positioned inside the chamber interior 514.

In some embodiments, the apparatuses described herein may include a controller that is configured to control various aspects of the apparatus in order to perform the techniques described herein. For example, referring back to FIG. 5A, apparatus 500 includes a controller 531 (which may include one or more physical or logical controllers) that is communicatively connected with and that controls some or all of the operations of a processing chamber. The system controller 531 may include one or more memory devices 533 and one or more processors 535. In some embodiments, the apparatus includes a switching system for controlling flow rates and durations, the substrate heating unit, the substrate cooling unit, the loading and unloading of a substrate in the chamber, the thermal floating of the substrate, and the process gas unit, for instance, when disclosed embodiments are performed. In some embodiments, the apparatus may have a switching time of up to about 500 ms, or up to about 750 ms. Switching time may depend on the flow chemistry, recipe chosen, reactor architecture, and other factors.

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer.

In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

In some embodiments, the apparatus may further be configured to generate a plasma and use the plasma for some processing in various embodiments. This may include having a plasma source configured to generate a plasma within the chamber interior, such as a capacitively coupled plasma (CCP), an inductively coupled plasma (ICP), an upper remote plasma, and a lower remote plasma.

The apparatuses described herein may be used for various etching techniques including, but not limited to, continuous etching methods and cyclic methods such as atomic layer etching.

### EXPERIMENTAL

A series of semiconductor substrates was prepared and etched to demonstrate the high quality etching results that can be achieved using the disclosed embodiments. Specifically, several substrates were prepared by depositing a blanket layer of silicon oxide thereon. The substrates were etched using the method of FIG. 2. The reactant gas included NH₄OH, H₂O, and HF. The NH₄OH was dissolved in liquid H₂O prior to vaporization and delivery to the processing chamber. The modification step described in operation 201 of FIG. 2 was performed for about 60 seconds at several different temperatures, with different temperatures being used for different substrates. The pressure in the processing chamber was about 0.5 Torr. After the modification step, the substrates were analyzed using FTIR to look for salt formation. The substrates were then subjected to a removal step that involved exposing each substrate to a bake at a temperature of about 130° C. for a duration of about 60 seconds, corresponding to operation 205 of FIG. 2. After the removal step, the substrates were again analyzed using FTIR to confirm removal of the salt.

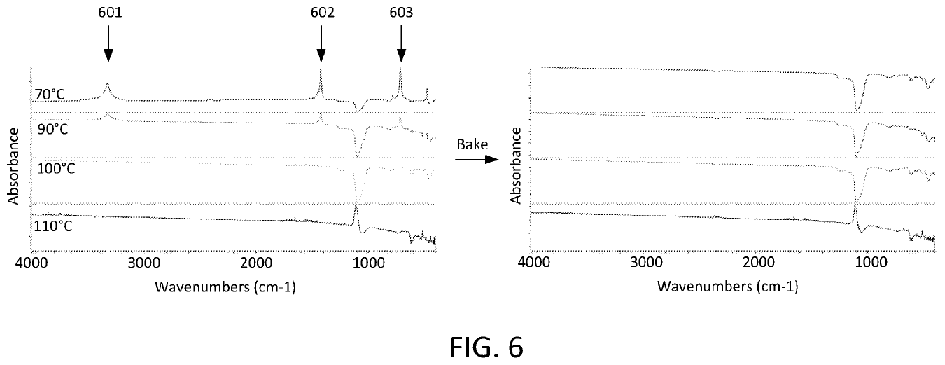

The left portion of FIG. 6 shows the post-modification results for substrates processed at 70° C., 90° C., 100° C., and 110° C. The peaks shown at arrows 601, 602, and 603 correspond to the ammonium fluorosilicate salt. These peaks are substantial for the substrate processed at about 70° C. (and at lower temperatures, not shown). The peaks are less substantial but still apparent for the substrate processed at about 90° C. For the substrate processed at about 100° C., the peaks are very small or non-existent, indicating that little or no salt was forming at these particular conditions. Similarly, no salt formation is evident for the substrate processed at about 110° C.

The right portion of FIG. 6 shows the post-removal results for the substrates shown in the left portion of the figure. Notably, none of the substrates showed peaks at the relevant locations, indicating that any salt formed during the modification step was effectively removed during the removal step.

These results illustrate that the disclosed methods can be used to etch silicon oxide from a semiconductor substrate as desired. For instance, the disclosed methods can be used to etch silicon oxide in a cyclic method that involves modification of the silicon oxide to an ammonium fluorosilicate salt, followed by removal of the fluorosilicate salt. Notably, the disclosed methods can be accomplished at modification temperatures significantly higher than those used previously. As a result, there is a much smaller temperature differential between the modification and removal steps. This smaller temperature differential allows processing to occur relatively quickly even in a single reaction chamber, thereby providing high throughput and minimizing both processing and capital costs.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method of etching a substrate, the method comprising:
receiving a substrate having an oxide material thereon; and
exposing the substrate to a reactant gas to etch the oxide material on the substrate, wherein the reactant gas is in a vapor phase and comprises an ammonium-based hydroxide source. 2 The method of claim 1, wherein the reactant gas is generated, at least in part, by vaporizing a solution comprising the ammonium-based hydroxide source and a solvent.

3. The method of claim 1, wherein exposing the substrate to reactant gas comprises:
exposing the substrate to the reactant gas at a first temperature to form a salt on the substrate, and
exposing the substrate to a second temperature to remove the salt from the substrate, wherein the second temperature is higher than the first temperature.

4. The method of claim 3, wherein the first temperature is about 90° C. or less, and wherein the second temperature is about 100° C. or greater.

5. The method of claim 4, wherein the first temperature is about 50° C. or greater.

6. The method of claim 3, wherein a difference between the first temperature and the second temperature is about 60° C. or less.

7. The method of claim 6, wherein the difference between the first temperature and the second temperature is about 20° C. or less.

8. The method of claim 3, wherein the substrate is exposed to the reactant gas and to the first temperature and the second temperature within a single reaction chamber.

9. The method of claim 1, wherein the oxide material comprises a first portion that is heterogeneous with respect to oxide density and a second portion that is homogeneous with respect to oxide density,
wherein exposing the substrate to the reactant gas comprises exposing the first portion of the oxide material to the reactant gas, and
exposing the second portion of the oxide material to a second reactant gas, wherein the second reactant gas comprises a solvent and a halogen source, and does not comprise the ammonium-based hydroxide source.

10. The method of claim 9, wherein the second reactant gas comprises pyridine.

11. The method of claim 1, wherein the ammonium-based hydroxide source comprises ammonium hydroxide or a substituted form of ammonium hydroxide.

12. The method of claim 11, wherein the ammonium-based hydroxide source comprises one or more alkyl groups bonded to a nitrogen of the ammonium-based hydroxide source.

13. The method of claim 12, wherein the ammonium-based hydroxide source comprises four alkyl groups bonded to the nitrogen of the ammonium-based hydroxide source.

14. The method of claim 13, wherein the ammonium-based hydroxide source comprises one or more reactant from the group consisting of tetramethylammonium hydroxide, tetraethylammonium hydroxide, tetrapropyl ammonium hydroxide, and combinations thereof.

15. The method of claim 2, wherein the solution from which the reactant gas is at least partially generated comprises water.

16. The method of claim 2, wherein the solution from which the reactant gas is at least partially generated comprises at least one solvent selected from the group consisting of acetone, acetonitrile, an alcohol, chloroform, dichlorobenzene, dichloroethane, dimethylacetamide, dimethylformamide, dimethylsulfoxide, formamide, hexamethylphosphoramide, nitrobenzene, nitromethane, pyridine, and combinations thereof.

17. The method of claim 1, wherein the reactant gas further comprises a halogen source.

18. The method of claim 17, wherein the halogen source is selected from the group consisting of HF, F₂, and combinations thereof.

19. An apparatus for etching a substrate, the apparatus comprising:
one or more process chambers, each process chamber comprising a substrate holder;
one or more gas inlets into the process chambers and associated flow-control hardware; and
a controller having at least one processor and a memory, wherein
the at least one processor and the memory are communicatively connected with one another,
the at least one processor is at least operatively connected with the flow-control hardware, and
the memory stores computer-executable instructions for controlling the at least one processor to at least control the flow-control hardware to:
cause the substrate to be exposed to a reactant gas, thereby causing removal of an oxide material from the substrate, wherein the reactant gas is in a vapor phase and comprises an ammonium-based hydroxide source.
